(19) United States
(12) Patent Application Publication
(10) Pub. No.: US 2007/0158105 A1
(43) Pub. Date: Jul. 12, 2007

(54) MULTILAYER WIRING BOARD CAPABLE OF REDUCING NOISE OVER WIDE FREQUENCY BAND WITH SIMPLE STRUCTURE

(76) Inventors: Kohji Kitao, Osaka (JP); Hiroshi Kamiya, Osaka (JP); Takanori Saeki, Kawasaki-shi (JP)

Correspondence Address: HAYES, SOLOWAY P.C., 3450 E. SUNRISE DRIVE, SUITE 140, TUCSON, AZ, 85718, US

(21) Appl. No.: 11/560,748

(22) Filed: Nov. 16, 2006

(30) Foreign Application Priority Data
Nov. 18, 2005 (JP) 2005-334216
Oct. 26, 2006 (JP) 2006-291246

(51) Int. Cl. H05K 1/11; H05K 3/02

(52) U.S. Cl. 174/261; 174/250; 29/846; 29/830

(57) ABSTRACT

A multilayer wiring board 10 has a high-capacitance layer 121 formed between a ground layer 141 and a power supply layer 15 and a high-capacitance layer 122 formed between the power supply layer 15 and a ground layer 142. The high-capacitance layers 121 and 122 are different in capacitance from each other. The multilayer wiring board 10 incorporates two capacitors which share the power supply layer 15 with each other and which are different in capacitance from each other.

This application claims priority to prior Japanese patent applications JP 2005-334216 and JP 2006-291246, the disclosures of which are incorporated herein by reference.

### BACKGROUND OF THE INVENTION

This invention relates to a multilayer wiring board and, in particular, relates to a multilayer wiring board having a capacitor function between a power supply layer and a ground layer for noise suppression of the board.

In recent years, reduction in size and weight and advanced functionality have been required for portable electronic devices such as portable telephones and notebook personal computers. Following it, increase in transmission rate, in addition to high-density wiring and reduction in size and weight, has been required for circuit boards for use in semiconductor or LSI packages and so on.

However, following the increase in signal speed, there arises a problem that noise, which is not a problem at low speeds, prevents transmission of information. In order to increase the transmission rate, a circuit board design is required that can reduce the noise.

Generally, there has been employed a method that reduces electrical noise by mounting decoupling capacitors on a multilayer wiring board.

However, the signal transmission frequency has been increased more and more in recent years and, following it, the number of capacitors mounted on a board has also been increased. Using many capacitors makes a wiring design difficult, for example, making it impossible to provide the shortest wiring between components and making it difficult to achieve synchronization, and, further, it prevents miniaturization of a circuit board and causes an increase in cost.

In view of this, in recent years, a method has been proposed that reduces electrical noise by providing a layer made of a high-permittivity material in a multilayer wiring board of an LSI package or the like and thus incorporating a structure adapted to function as a capacitor in the multilayer wiring board. Such a technique is disclosed, for example, in Japanese Unexamined Utility Model Application Publication (JP-U) No. Hei 07-10979 or Japanese Unexamined Patent Application Publication (JP-A) No. 2002-217545. In this method, since the capacitor can be disposed right under an LSI, the LSI and the capacitor can be connected together by a much shorter line as compared with the case of a decoupling capacitor mounted on a board and thus the circuit parasitic inductance can be reduced, thereby enabling a reduction in noise of an LSI power supply.

However, as regards the multilayer wiring board disclosed in JP-U No. Hei 07-10979, there has been a problem that it is still necessary to add decoupling capacitors on the board or the LSI package with respect to noise in a frequency band that cannot be removed by the high-permittivity material incorporated in the multilayer wiring board.

Further, as regards the multilayer wiring board disclosed in JP-A No. 2002-217545, since a capacitance layer is provided for each supply-ground layer pair comprised of a power supply layer and a ground layer, the total number of layers is large and the structure is complicated, and therefore, miniaturization of the circuit board cannot be sufficiently achieved.

### SUMMERY OF THE INVENTION

It is therefore an object of this invention to provide a multilayer wiring board that can reduce noise in the board over a wide frequency band with a simple structure.

According to an aspect of this invention, there is provided a multilayer wiring board comprising first, second, and third conductive layers, a first insulating layer formed between the first and the second conductive layers, and a second insulating layer formed between the second and the third conductive layers. The first and the second insulating layers are different in capacitance from each other.

According to another aspect of this invention, there is provided a multilayer wiring board comprising first, second, third, and fourth conductive layers, a first insulating layer formed between the first and the second conductive layers, a second insulating layer formed between the second and the third conductive layers, and a third insulating layer formed between the third and the fourth conductive layers. At least two of the first, the second, and the third insulating layers are different in capacitance from one another.

According to still another aspect of this invention, there is provided a multilayer wiring board comprising an inner conductive layer which is sandwiched between first and second insulating layer and which is further sandwiched between two outer conductive layers. The inner conductive layer serves as one of a power supply layer and a ground layer. Each of the outer conductive layers serves as the other of the power supply layer and the ground layer. The first and the second insulating layers are different in capacitance from each other.

According to another aspect of this invention, there is provided a multilayer wiring board comprising an inner conductive layer which is sandwiched between first and second insulating layer and which is further sandwiched between two outer conductive layers and an additional outer conductive layer formed on one of the outer conductive layers through a third insulating layer. The inner conductive layer serves as one of a power supply layer and a ground layer. Each of the outer conductive layers serves as the other of the power supply layer and the ground layer. The additional outer conductive layer serves as a secondary power supply layer or a secondary ground layer. At least two of the first, the second, and the third insulating layers are different in capacitance from one another.

According to another aspect of this invention, there is provided a multilayer wiring board manufacturing method comprising the steps of forming conductive layers on both sides of a first capacitance layer, thereby fabricating a first member, forming a conductive layer on one side of a second capacitance layer, thereby fabricating a second member, and stacking together the first and the second member by pressing such that a surface, not formed with the conductive layer, of the second member is butted to one of the conductive layers of the first member. The first and the second capacitance layers are different in capacitance from each other.

According to another aspect of this invention, there is provided a multilayer wiring board manufacturing method comprising the steps of forming conductive layers on both sides of a first capacitance layer, thereby fabricating a first member, forming a conductive layer on one side of a second capacitance layer, thereby fabricating a second member, forming a conductive layer on one side of a third capacitance layer, thereby fabricating a third member, and stacking together the first, the second, the third members by pressing such that a surface, not formed with the conductive layer, of the second member is butted to the one of the conductive layers of the first member and that a surface, not formed with the conductive layer, of the third member is butted to the other of the conductive layers of the first member. At least two of the first, the second, and the third capacitance layers are different in capacitance from one another.

### BRIEF DESCRIPTION OF THE DRAWINGS:

FIG. 1 is a perspective view of a conventional multilayer wiring board;

FIG. 2 is a sectional view of the multilayer wiring board taken along line 2-2 in FIG. 1;

FIG. 3 is a perspective view of a multilayer wiring board according to a first embodiment of this invention;

FIG. 4 is a sectional view of the multilayer wiring board taken along line 4-4 in FIG. 3;

FIG. 5 is a diagram showing an example simulating changes in impedance with respect to frequency using the multilayer wiring board of FIGS. 3 and 4;

FIG. 6 is a sectional view of a multilayer wiring board according to a modification of the first embodiment of this invention;

FIGS. 7A to 7D are diagrams showing a method of manufacturing the multilayer wiring board according to the first embodiment of this invention;

FIG. 8 is a sectional view of a multilayer wiring board according to a second embodiment of this invention;

FIGS. 9A to 9D are diagrams showing a method of manufacturing the multilayer wiring board according to the second embodiment of this invention;

FIG. 10 is a sectional view of a multilayer wiring board according to a third embodiment of this invention;

FIG. 11 is a sectional view of a multilayer wiring board according to a fourth embodiment of this invention; and

FIGS. 12A to 12E are sectional views of multilayer wiring boards according to fifth to ninth embodiments of this invention.

### DESCRIPTION OF THE PREFERRED EMBODIMENTS:

In order to facilitate understanding of this invention, a conventional multilayer wiring board will first be described.

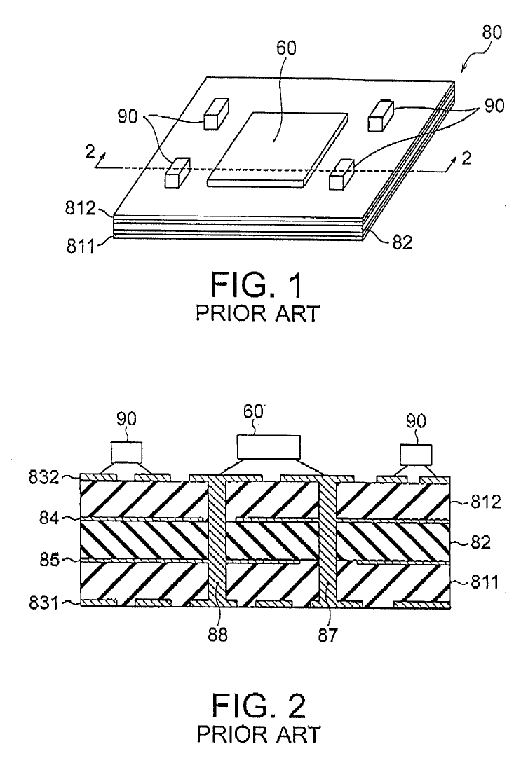

FIG. 1 is a perspective view of the conventional multilayer wiring board.

In FIG. 1, a multilayer wiring board 80 comprises low-capacitance layers 811 and 812 made of an insulating material generally used in circuit boards and having the same low capacitance and a high-capacitance layer 82 having a capacitance higher than that of each of the low-capacitance layers 811 and 812. The low-capacitance layers 811 and 812 are respectively disposed on the back side of the multilayer wiring board 80 and on the front side thereof where an electronic component 60 such as an LSI chip is mounted. On the multilayer wiring board 80 are mounted decoupling capacitors 90 for the purpose of reducing power supply noise of the LSI chip.

FIG. 2 is a sectional view of the multilayer wiring board taken along line 2-2 in FIG. 1.

Conductive layers disposed on the low-capacitance layers 811 and 812 on the back and front sides of the multilayer wiring board 80 are signal layers 831 and 832, respectively. The signal layers 831 and 832 are connected to the electronic component 60 such as the LSI chip, mounted on the front side, through bonding wires. Between the two signal layers 831 and 832, the low-capacitance layer 811, a power supply layer 85, the high-capacitance layer 82, a ground layer 84, and the low-capacitance layer 812 are stacked in the order named from below. The electronic component 60 such as the LSl chip is connected to the ground layer 84 and the power supply layer 85 through a ground via 87 and a power supply via 88, respectively.

On the other hand, according to this invention, a multilayer wiring board incorporates a structure that exhibits the function of two or more capacitors. Therefore, it is possible to reduce noise over a wide frequency band and, further it is possible to reduce the number of decoupling capacitors or eliminate them all.

Further, this invention provides a structure in which at least one of a supply-ground layer pair comprised of a power supply layer and a ground layer with an insulating layer having a capacitance therebetween is also used for another supply-ground layer pair. Accordingly, there is an effect that the total number of layers is smaller and the structure is simpler as compared with the conventional structure having a plurality of supply-ground layer pairs independent of each other.

Hereinbelow, embodiments of this invention will be described in detail with reference to the drawings.

### FIRST EMBODIMENT

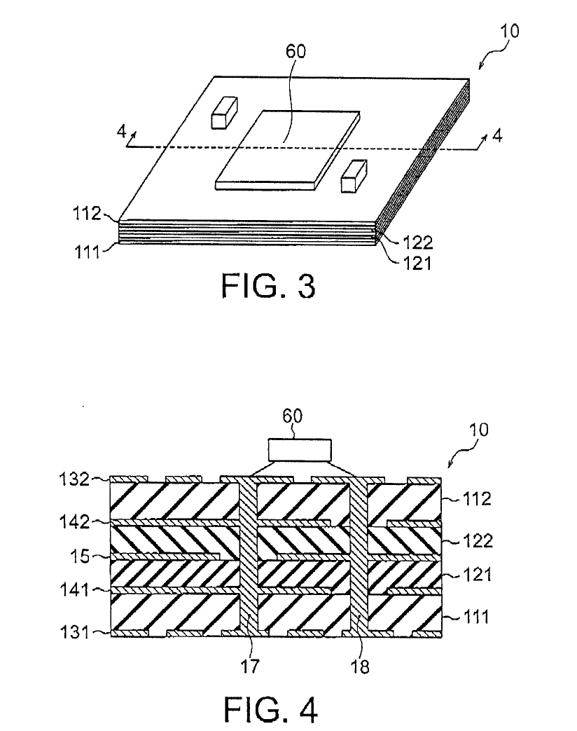

FIG. 3 is a perspective view of a multilayer wiring board according to the first embodiment of this invention.

A multilayer wiring board 10 comprises low-capacitance layers 111 and 112 made of an insulating material generally used in circuit boards and having the same low capacitance between conductive layers, and two high-capacitance layers 121 and 122 each having a capacitance between conductive layers which is higher than that of each of the low-capacitance layers 111 and 112.

The low-capacitance layers 111 and 112 are respectively disposed on the back side of the multilayer wiring board 10 and on the front side thereof where an electronic component 60 such as an LSI chip is mounted.

The high-capacitance layers 121 and 122 have mutually different capacitances and are disposed adjacent to each other.

FIG. 4 is a sectional view of the multilayer wiring board taken along line 4-4 in FIG. 3.

Conductive layers disposed on the low-capacitance layers 111 and 112 on the back and front sides of the multilayer wiring board 10 are signal layers 131 and 132, respectively. The signal layer 132 is connected to the electronic component 60 such as the LSI chip, mounted on the front side, through bonding wires, Between the two signal layers 131 and 132, the low-capacitance layer 111, a ground layer 141, the high-capacitance layer 121, a power supply layer 15, the high-capacitance layer 122, a ground layer 142, and the low-capacitance layer 112 are stacked in the order named from below.

The signal layers 131 and 132, the ground layers 141 and 142, and the power supply layer 15 may be in the form of copper foils, but not limited thereto, and may be made of a material generally used for conductive layers of multilayer wiring boards.

As described above, the multilayer wiring board 10 of this invention is formed by sandwiching the power supply layer 15 between the high-capacitance layers 121 and 122 having mutually different capacitances, further sandwiching them between the ground layers 141 and 142, and further sandwiching them between the signal layers 131 and 132 through the low-capacitance layers 111 and 112,

The signal layers 131 and 132 include ground wires, power supply wires, and signal wires, respectively. A ground via 17 is formed between the ground wires of the signal layers 131 and 132 and the ground layers 141 and 142. A power supply via 18 is formed between the power supply wires of the signal layers 131 and 132 and the power supply layer 15. Although not illustrated, a via may be formed between the signal wire of the signal layer 131 on the back side and the signal wire of the signal layer 132 on the front side. As shown in FIG. 4, it may be arranged that the ground wires and the power supply wires of the signal layers 131 and 132 are located at the same horizontal positions, i.e. at the same positions in a direction perpendicular to the signal layers 131 and 132, and the ground via 17 and the power supply via 18 pass through the multilayer wiring board 10 so as to be connected to the ground wires and the power supply wires of the signal layers 131 and 132, respectively.

Basically, the ground layers 141 and 142 and the power supply layer 15 are formed in the maximum ranges that avoid interference with the power supply via 18 and the ground via 17, respectively.

The insulating material of the low-capacitance layers 111 and 112 has, for example, a relative permittivity of approximately 2 to 5. The insulating material of the low-capacitance layers 111 and 112 is obtained, for example, by impregnating a glass cloth with an epoxy resin and drying them, but is not limited thereto. Assuming, for example, that use is made of a material having a relative permittivity of 4.2 and its thickness is set to 200 μm, the capacitance per unit area is approximately 0.2 pF/mm².

The capacitance of the high-capacitance layer 122 is set to a value that can substitute for that of a small-capacitance decoupling capacitor adapted to absorb high-frequency noise. As defined by the following formula (1), the capacitance C of a capacitor is proportional to an electrode area A and a relative permittivity εr of a dielectric and inversely proportional to a distance d between electrodes.
C =ε0·εr·A/d (1)

(ε0: vacuum permittivity)

For example, using the same insulating material as that of the low-capacitance layers 111 and 112 with the relative permittivity of 4.2 and setting its thickness to 50 μm, the capacitance is set to 0.78 pF/mm².

The capacitance of the high-capacitance layer 121 is set to a value that can substitute for that of a large-capacitance decoupling capacitor adapted to absorb power supply ripple voltage or the like, and is preferably set to 2 pF/mm² or more. In this embodiment, as an insulating material of the high-capacitance layer 121, use is made of a material whose permittivity is increased as compared with that of the high-capacitance layer 122. For example, use is made of a material obtained by filling a barium titanate-based high-permittivity filler into an epoxy resin of the same insulating material as that of the high-capacitance layer 122 so as to obtain a relative permittivity of 16. By setting its thickness to 50 μm, the capacitance of the high-capacitance layer 121 is set to 2.8 pF/mm².

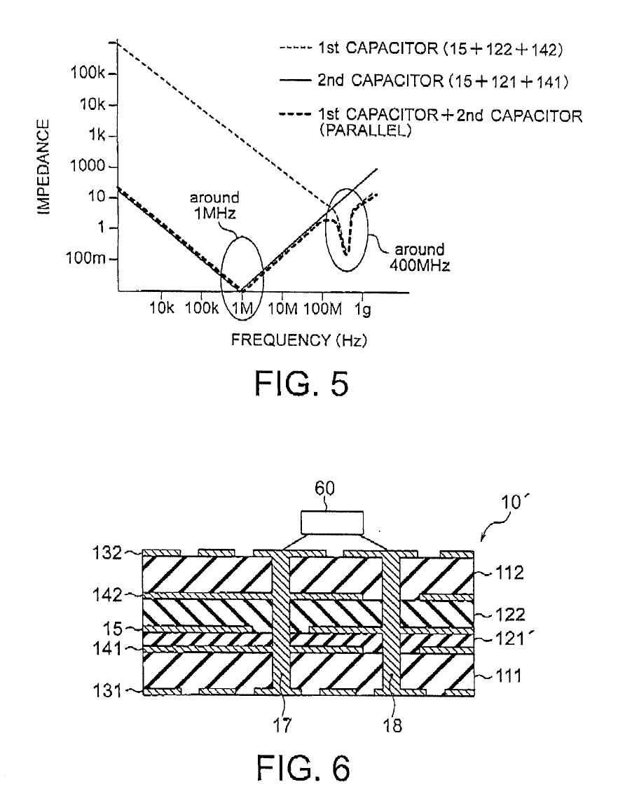

As described above, in this embodiment, the dielectric materials of the high-capacitance layers 121 and 122 respectively have the capacitances that differ from each other. The effect of this will be explained with reference to FIG. 5.

FIG. 5 is a diagram showing an example simulating changes in impedance with respect to frequency using the multilayer wiring board of FIGS. 3 and 4. A first capacitor formed by the power supply layer 15, the high-capacitance layer 122, and the ground layer 142 exhibited the lowest impedance around 400 MHz. On the other hand, a second capacitor formed by the power supply layer 15, the high-capacitance layer 121, and the ground layer 141 exhibited the lowest impedance around 1 MHz. Then, the multilayer wiring board of this embodiment having both of them exhibited those low impedances at two frequencies, i.e. around 1 MHz and around 400 MHz. Accordingly, it was demonstrated that when the capacitors having mutually different capacitances were provided together, there were obtained the noise reduction effects in the corresponding frequency bands, respectively.

Further, this embodiment is configured such that the power supply layer 15 of a supply-ground layer pair comprised of the power supply layer 15 and the ground layer 142 with the high-capacitance layer 122 interposed therebetween is also used in the other supply-ground layer pair having the high-capacitance layer 121 interposed therebetween. Accordingly, there is an effect that the total number of layers is smaller and the structure is simpler as compared with the conventional structure having a plurality of supply-ground layer pairs independent of each other.

Now, a modification of this embodiment will be described. FIG. 6 is a sectional view of a multilayer wiring board according to the modification of the first embodiment of this invention. The same symbols as those in FIGS. 3 and 4 represent the same or equivalent components.

This modification differs from the embodiment of FIGS. 3 and 4 in that a high-capacitance layer 121′ having a larger capacitance than a high-capacitance layer 122 is formed by reducing the thickness of an insulating material having the same permittivity as that of the high-capacitance layer 122.

The high-capacitance layer 121′ is made of the same insulating material as that of low-capacitance layers 111 and 112 and the high-capacitance layer 122 with a relative permittivity of 4.2 and, for example, by setting its thickness to 25 μm, the capacitance is set to 1.56 pF/mm². With this configuration, since the respective layers are made of the same insulating material, i.e. use is not made of insulating materials having different permittivities for the respective layers, thermal expansion coefficients and so on of the low-capacitance layers 111 and 112 and the two high-capacitance layers 121′ and 122 are equal to each other, thus resulting in higher reliability.

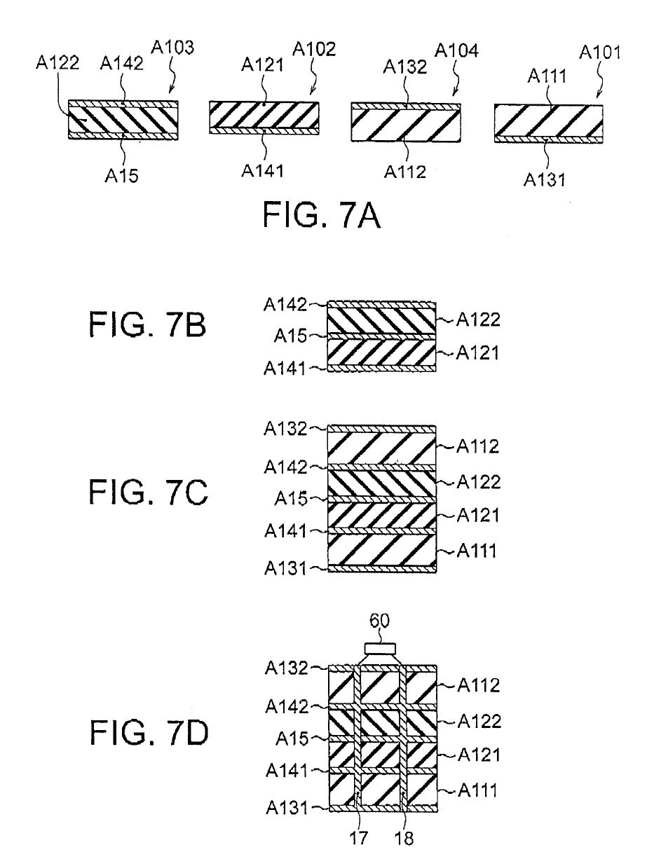

Referring now to FIGS. 7A to 7D, description will be made of a method of manufacturing the multilayer wiring board according to this embodiment.

(Process 1) There are prepared resin-formed copper foils or copper foil-clad resin members each comprising an insulating member of the corresponding layer and a copper foil attached to one side or each of both sides of the insulating member.

Specifically, for manufacturing the board according to the embodiment shown in FIGS. 3 and 4, a core member (dual copper foil-clad resin member) A103 as a first member, a copper foil-clad resin member A102 as a second member, a copper foil-clad resin member A101 as a third member, and a copper foil-clad resin member A104 as a fourth member are respectively prepared as shown in FIG. 7A.

The copper foil-clad resin member A101 is such that a copper foil A131 is attached to one side of a member A111 having a relative permittivity of 4.2 and a thickness of 200 μm, which is obtained by impregnating a glass cloth with an epoxy resin and drying them. The copper foil-clad resin member A102 is such that a copper foil A141 is attached to one side of a member A121 having a relative permittivity of 16 and a thickness of 50 μm, which is obtained by impregnating a glass cloth with an epoxy resin filled with a barium titanate-based high-permittivity filler and drying them. The core member A103 is such that copper foils A15 and A142 are attached to both sides of a member A122 having a relative permittivity of 4.2 and a thickness of 50 μm, which is obtained by impregnating a glass cloth with an epoxy resin and drying them.

The copper foil-clad resin member A104 is such that a copper foil A132 is attached to one side of a member A112 having a relative permittivity of 42 and a thickness of 200 μm, which is obtained by impregnating a glass cloth with an epoxy resin and drying them.

When manufacturing the board according to the modification shown in FIG. 6, there is prepared, instead of the copper foil-clad resin member A102, a copper foil-clad resin member in which a copper foil is attached to one side of a member having a relative permittivity of 4.2 and a thickness of 25 μm, which is obtained by impregnating a glass cloth with an epoxy resin and drying them.

The copper foil A15, the copper foils A141 and A142, and the copper foils A131 and A132 are all formed with circuits by etching.

(Process 2) As shown in FIG. 7B, the core member A103 and the copper foil-clad resin member 102 prepared in Process 1 are stacked together by pressing to form a base structure.

(Process 3) As shown in FIG. 7C, the copper foil-clad resin members A101 and A104 are built up on the base structure, formed in Process 2, from the lower and upper sides thereof, respectively.

In Processes 1 to 3, five copper foils are stacked and thus a five-layer board is fabricated. The copper foil A15 corresponds to the power supply layer 15 in FIG. 4, the copper foils A141 and A142 correspond to the ground layers 141 and 142 in FIG. 4, and the copper foils A131 and A132 correspond to the signal layers 131 and 132 in FIG. 4.

(Process 4) As shown in FIG. 7D, a ground via 17, a power supply via 18, and so on are formed after the stacking, so that the copper foils A131 and A132, which will serve as the signal layers 131 and 132, are connected to the copper foils A141 and A142, which will serve as the ground layers 141 and 142, through the ground via 17 and to the copper foil A15, which will serve as the power supply layer 15, through the power supply via 18. Thereafter, an electronic component 60 such as an LSI chip is mounted on the copper foil A132 and connected thereto through bonding wires.

As described above, the multilayer wiring board of this invention is manufactured by preparing the copper foil-clad resin members each having the insulating member, which will serve as the high-capacitance layer, and the copper foil attached to one side or each of both sides of the insulating member, forming the copper foils with the circuits, pressing the copper foil-clad resin members, building up the copper foil-clad resin members each having the insulating member, which will serve as the low-capacitance layer, and then forming the ground via, the power supply via, and so on. Accordingly, it can be manufactured more efficiently and easily than forming layers one by one in sequence.

### SECOND EMBODIMENT

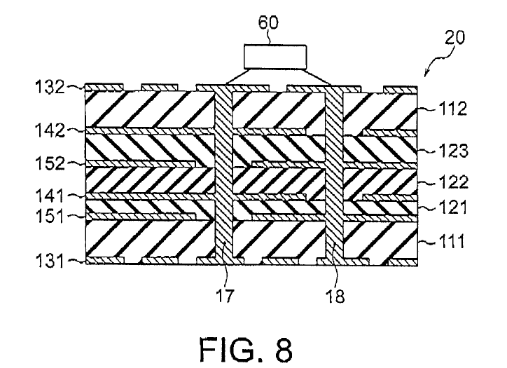

Now, referring to FIG. 8, description will be made of a multilayer wiring board according to the second embodiment of this invention, wherein three kinds of different high-capacitance layers are incorporated.

FIG. 8 is a sectional view of the multilayer wiring board according to the second embodiment of this invention.

A multilayer wiring board 20 comprises low-capacitance layers 111 and 112 made of an insulating material generally used in circuit boards and having a relatively low permittivity, and each sandwiched between conductive layers, and three high-capacitance layers 121, 122, and 123 each having a capacitance higher than that of each of the low-capacitance layers 111 and 112.

The low-capacitance layers 111 and 112 are respectively disposed on the back side of the multilayer wiring board 20 and on the front side thereof where an electronic component 60 such as an LSI chip is mounted.

The high-capacitance layers 121, 122, and 123 have mutually different capacitances and are disposed adjacent to each other.

Conductive layers disposed on the low-capacitance layers 111 and 112 on the back and front sides of the multilayer wiring board 20 are signal layers 131 and 132, respectively. The signal layer 132 is connected to the electronic component 60 such as the LSI chip, mounted on the front side, through bonding wires.

A conductive layer between the high-capacitance layer 123 and the low-capacitance layer 112 and a conductive layer between the high-capacitance layers 121 and 122 are ground layers 142 and 141, respectively. Further, a conductive layer between the high-capacitance layers 122 and 123 and a conductive layer between the high-capacitance layer 121 and the low-capacitance layer 111 are power supply layers 152 and 151, respectively. The signal layers 131 and 132, the ground layers 141 and 142, and the power supply layers 151 and 152 may be in the form of copper foils, but not limited thereto, and, like the signal layers, the ground layers, and the power supply layer in the first embodiment, may be made of a material generally used for conductive layers of multilayer wiring boards.

As described above, this embodiment incorporates two structures each corresponding to the structure of the first embodiment, That is, this embodiment includes a first structure in which the power supply layer 152 is sandwiched between the high-capacitance layers 122 and 123 having mutually different capacitances and further sandwiched between the ground layers 141 and 142, and a second structure in which the ground layer 141 is sandwiched between the high-capacitance layers 121 and 122 having mutually different capacitances and further sandwiched between the power supply layers 151 and 152. These first and second structures each correspond to the structure of the first embodiment.

Aground via 17 is formed between ground wires of the signal layers 131 and 132 and the ground layers 141 and 142. A power supply via 18 is formed between power supply wires of the signal layers 131 and 132 and the power supply layers 151 and 152. A via may be formed between a signal wire of the signal layer 132 on the front side and a signal wire of the signal layer 131 on the back side. Also in this embodiment, as shown in FIG. 8, it may be arranged that the ground wires and the power supply wires of the signal layers 131 and 132 are located at the same horizontal positions and the ground via 17 and the power supply via 18 pass through the multilayer wiring board 20 so as to be connected to the ground wires and the power supply wires of the signal layers 131 and 132, respectively.

Also in this embodiment, the ground layers 141 and 142 and the power supply layers 151 and 152 are basically formed in the maximum ranges that avoid interference with the power supply via 18 and the ground via 17, respectively.

Like in the first embodiment, the insulating material of the low-capacitance layers 111 and 112 has, for example, a relative permittivity of approximately 2 to 5. The insulating material of the low-capacitance layers 111 and 112 is obtained, for example, by impregnating a glass cloth with an epoxy resin and drying them, but is not limited thereto. Assuming, for example, that use is made of a material having a relative permittivity of 4.2 and its thickness is set to 200 μm, the capacitance per unit area is approximately 0.2 pF/mm².

The capacitance of the high-capacitance layer 123 is set to a value that can substitute for that of a small-capacitance decoupling capacitor adapted to absorb high-frequency noise. For example, like in the case of the high-capacitance layer 122 of the first embodiment, using the same insulating material as that of the low-capacitance layers 111 and 112 with the relative permittivity of 4.2 and setting its thickness to 50 μm, the capacitance is set to 0.78 pF/mm².

The capacitance of the high-capacitance layer 122 is set to a value that can substitute for that of a large-capacitance decoupling capacitor adapted to absorb power supply ripple voltage or the like, and is preferably set to 2 to 5 pF/mm². In this embodiment, as an insulating material of the high-capacitance layer 122, use is made of a material whose permittivity is increased as compared with that of the high-capacitance layer 123. For example, like in the case of the high-capacitance layer 121 of the first embodiment, use is made of a material obtained by filling a barium titanate-based high-permittivity filler into an epoxy resin of the same insulating material as that of the high-capacitance layer 123 so as to obtain a relative permittivity of 16. By setting its thickness to 50 μm, the capacitance of the high-capacitance layer 122 is set to 2.8 pF/mm².

The capacitance of the high-capacitance layer 121 is set to a value that can substitute for that of a still larger-capacitance decoupling capacitor, and is preferably set to 5 pF/mm² or more. In this embodiment, as an insulating material of the high-capacitance layer 121, use is made of a material whose permittivity is increased as compared with that of the high-capacitance layer 122. For example, use is made of a material obtained by filling a larger amount of a barium titanate-based high-permittivity filler into an epoxy resin of the same insulating material as that of the high-capacitance layer 123 so as to obtain a relative permittivity of 40. By setting its thickness to 30 μm, the capacitance of the high-capacitance layer 121 is set to 11 pF/mm².

As described above, in this embodiment, since the capacitances of at least two of the high-capacitance layers 121, 122, and 123 differ from each other, the noise reduction effects are obtained in a plurality of frequency bands.

Instead of the high-capacitance layers 122 and 123, high-capacitance layers each having a smaller capacitance than the high-capacitance layer 121 may be formed by increasing the thickness of the insulating material having the same permittivity as that of the high-capacitance layer 121. On the other hand, instead of the high-capacitance layers 122 and 123, use may be made of high-capacitance layers obtained by reducing and increasing the thickness of the insulating material having the same permittivity as that of the high-capacitance layer 121, respectively. With this configuration, since the high-capacitance layers are made of the same insulating material, thermal expansion coefficients and so on of the respective layers are equal to each other, thus resulting in higher reliability.

In this embodiment, the power supply layer 152 of a supply-ground layer pair comprised of the power supply layer 152 and the ground layer 142 with the high-capacitance layer 123 interposed therebetween is also used in another supply-ground layer pair having the high-capacitance layer 122 interposed therebetween. Further, the ground layer 141 of a supply-ground layer pair comprised of the power supply layer 152 and the ground layer 141 with the high-capacitance layer 122 interposed therebetween is also used in still another supply-ground layer pair having the high-capacitance layer 121 interposed therebetween. Accordingly, there is an effect that the total number of layers is smaller and the structure is simpler as compared with the conventional structure having a plurality of supply-ground layer pairs independent of each other.

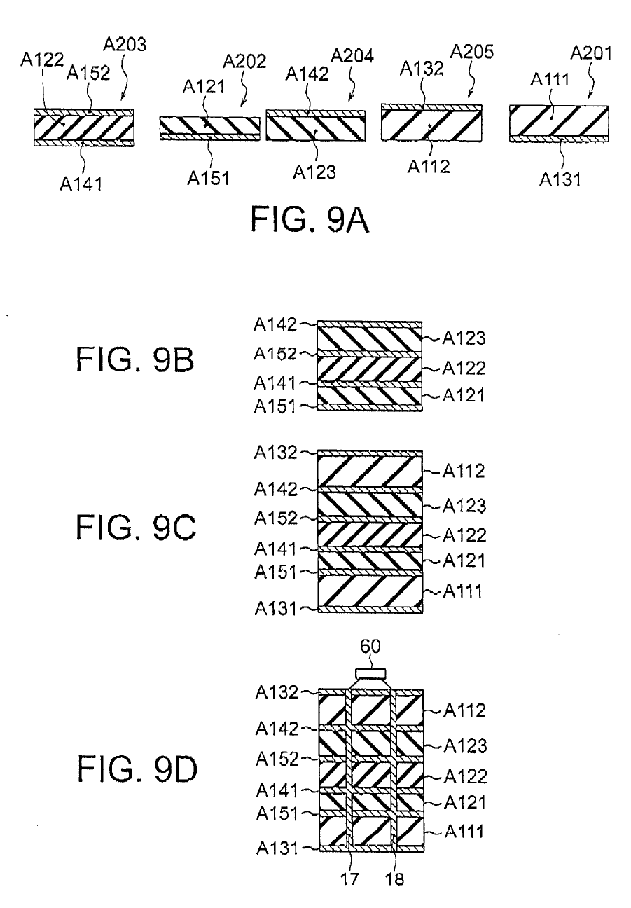

Referring now to FIGS. 9A to 9D, description will be made of a method of manufacturing the multilayer wiring board according to this embodiment.

(Process 1) There are prepared resin-formed copper foils or copper foil-clad resin members each comprising an insulating member of the corresponding layer and a copper foil attached to one side or each of both sides of the insulating member. Specifically, as shown in FIG. 9A, a core member (dual copper foil-clad resin member) A203 as a first member, a copper foil-clad resin member A202 as a second member, a copper foil-clad resin member A204 as a third member, a copper foil-clad resin member A201 as a fourth member, and a copper foil-clad resin member A205 as a fifth member are respectively prepared.

The copper foil-clad resin member A201 is such that a copper foil A131 is attached to one side of a member A111 having a relative permittivity of 4.2 and a thickness of 200 μm, which is obtained by impregnating a glass cloth with an epoxy resin and drying them. The copper foil-clad resin member A202 is such that a copper foil A151 is attached to one side of a member A121 having a relative permittivity of 40 and a thickness of 30 μm, which is obtained by impregnating a glass cloth with an epoxy resin filled with a barium titanate-based high-permittivity filler and drying them, The core member A203 is such that copper foils A141 and A152 are attached to both sides of a member A122 having a relative permittivity of 16 and a thickness of 50 μm, which is obtained by impregnating a glass cloth with an epoxy resin filled with a smaller amount of a barium titanate-based high-permittivity filler and drying them. The copper foil-clad resin member A204 is such that a copper foil A142 is attached to one side of a member A123 having a relative permittivity of 4.2 and a thickness of 50 μm, which is obtained by impregnating a glass cloth with an epoxy resin and drying them. The copper foil-clad resin member A205 is such that a copper foil A132 is attached to one side of a member A112 having a relative permittivity of 4.2 and a thickness of 200 μm, which is obtained by impregnating a glass cloth with an epoxy resin and drying them.

All the copper foils are formed with circuits by etching.

(Process 2) As shown in FIG. 9B, the core member A203 and the copper foil-clad resin members A202 and A204 prepared in Process 1 are stacked together by pressing to form a base structure.

(Process 3) As shown in FIG. 9C, the copper foil-clad resin members A201 and A205 are built up on the base structure, formed in Process 2, from the lower and upper sides thereof, respectively.

In Processes 1 to 3, six copper foils are stacked and thus a six-layer board is fabricated. The copper foils A141 and A142 correspond to the ground layers 141 and 142 in FIG. 8, the copper foils A151 and A152 correspond to the power supply layers 151 and 152 in FIG. 8, and the copper foils A131 and A132 correspond to the signal layers 131 and 132 in FIG. 8.

(Process 4) As shown in FIG. 9D, a ground via 17, a power supply via 18, and so on are formed after the stacking, so that the copper foils A131 and A132, which will serve as the signal layers 131 and 132, are connected to the copper foils A141 and A142, which will serve as the ground layers 141 and 142, through the ground via 17 and to the copper foils A151 and A152, which will serve as the power supply layers 151 and 152, through the power supply via 18. Thereafter, an electronic component 60 such as an LSI chip is mounted on the copper foil A132, which will serve as the signal layer 132, and connected thereto through bonding wires.

As described above, the multilayer wiring board of this invention is manufactured by preparing the copper foil-clad resin members each having the insulating member, which will serve as the high-capacitance layer, and the copper foil attached to one side or each of both sides of the insulating member, forming the copper foils with the circuits, pressing the copper foil-clad resin members, building up the copper foil-clad resin members each having the insulating member, which will serve as the low-capacitance layer, and then forming the ground via, the power supply via, and so on. Accordingly, it can be manufactured more efficiently and easily than forming layers one by one in sequence.

### THIRD EMBODIMENT

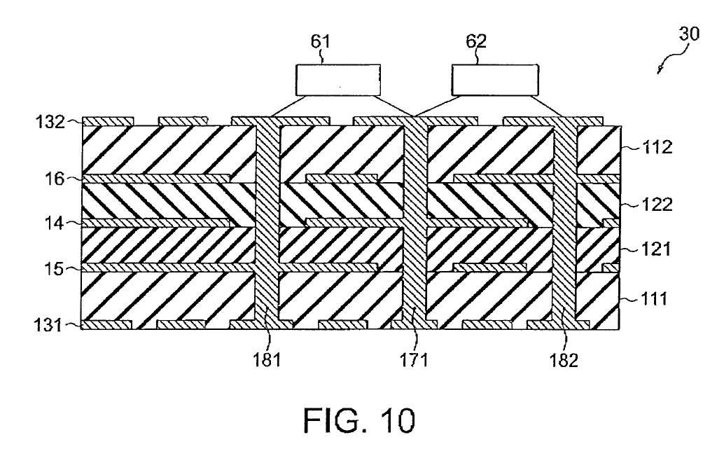

FIG. 10 is a sectional view of a multilayer wiring board according to the third embodiment of this invention.

The third embodiment of this invention has a structure such that the power supply layer and the ground layers in the first embodiment shown in FIG. 4 are replaced by a ground layer and power supply layers, respectively. Accordingly, the same symbols are assigned to components in FIG. 10 which are the same as or equivalent to those in the first embodiment, thereby omitting detailed explanation thereof.

Referring to FIG. 10, in a multilayer wiring board 30 according to the third embodiment of this invention, a low-capacitance layer 111, a first power supply layer 15, a high-capacitance layer 121, a ground layer 14, a high-capacitance layer 122, a second power supply layer 16, and a low-capacitance layer 112 are stacked between signal layers 131 and 132 in the order named from below.

The low-capacitance layers 111 and 112 are respectively disposed on the back side of the multilayer wiring board 30 and on the front side thereof where electronic components 61 and 62 such as LSI chips are mounted.

The signal layers 131 and 132 include ground wires, first power supply wires, second power supply wires, and signal wires, respectively, A ground via 17 is formed between the ground wires of the signal layers 131 and 132 and the ground layer 14. A first power supply via 181 is formed between the first power supply wires of the signal layers 131 and 132 and the first power supply layer 15. A second power supply via 182 is formed between the second power supply wires of the signal layers 131 and 132 and the second power supply layer 16.

In an LSI package having a variety of power supplies, it is possible to provide different high-capacitance layers for the respective power supplies, thereby achieving noise reduction effects in different frequency bands for the respective power supplies. For example, assuming that the operating frequency of a circuit of the LSI chip 61 operated by a power supply V1 connected to the first power supply layer 15 is 1 GHz, while the operating frequency of a circuit of the LSI chip 62 operated by a power supply V2 connected to the second power supply layer 16 is 100 MHZ, the frequency bands of noise also differ from each other. Accordingly, by providing insulating layers having different capacitances (high-capacitance layers 121 and 122), it is possible to adapt to the respective frequency bands.

Also in this embodiment, the high-capacitance layer 121 having a larger capacitance than the high-capacitance layer 122 may be formed by reducing the thickness of an insulating material having the same permittivity as that of the high-capacitance layer 122. Conversely, the high-capacitance layer 122 having a smaller capacitance than the high-capacitance layer 121 may be formed by increasing the thickness of an insulating material having the same permittivity as that of the high-capacitance layer 121. With this configuration, since the high-capacitance layers are made of the same insulating material, thermal expansion coefficients and so on of the respective layers are equal to each other, thus resulting in higher reliability.

Further, this embodiment is also configured such that the ground layer 14 of a supply-ground layer pair comprised of the first power supply layer 15 and the ground layer 14 with the high-capacitance layer 121 interposed therebetween is also used in the other supply-ground layer pair having the high-capacitance layer 122 interposed therebetween. Accordingly, there is an effect that the total number of layers is smaller and the structure is simpler as compared with the conventional structure having a plurality of supply-ground layer pairs independent of each other.

### FOURTH EMBODIMENT

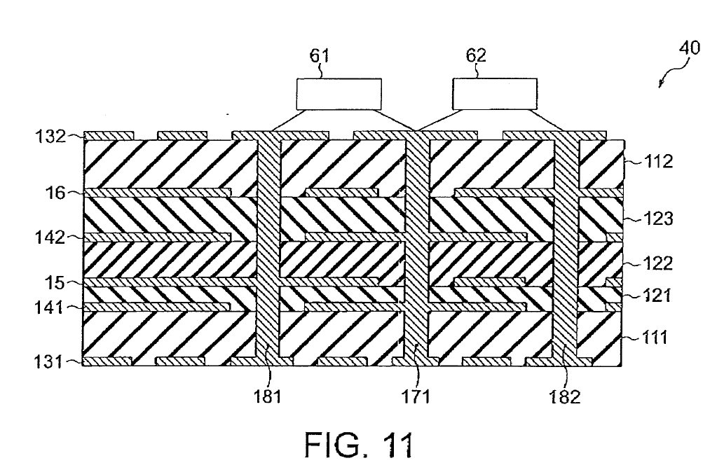

FIG. 11 is a sectional view of a multilayer wiring board according to the fourth embodiment of this invention.

The fourth embodiment of this invention has a structure such that the power supply layers and the ground layers in the second embodiment shown in FIG. 8 are exchanged therebetween. Accordingly, the same symbols are assigned to components in FIG. 11 which are the same as or equivalent to those in the second embodiment, thereby omitting detailed explanation thereof.

Referring to FIG. 11, a multilayer wiring board 40 comprises low-capacitance layers 111 and 112 made of an insulating material generally used in circuit boards and having a relatively low permittivity, and each sandwiched between conductive layers, and three high-capacitance layers 121, 122, and 123 each having a capacitance higher than that of each of the low-capacitance layers 111 and 112. The high-capacitance layers 121, 122, and 123 have mutually different capacitances and are disposed adjacent to each other.

The low-capacitance layers 111 and 112 are respectively disposed on the back side of the multilayer wiring board 40 and on the front side thereof where electronic components 61 and 62 such as LSI chips are mounted.

A conductive layer between the high-capacitance layer 123 and the low-capacitance layer 112 and a conductive layer between the high-capacitance layers 121 and 122 are a second power supply layer 16 and a first power supply layer 15, respectively. Further, a conductive layer between the high-capacitance layers 122 and 123 and a conductive layer between the high-capacitance layer 121 and the low-capacitance layer 111 are ground layers 142 and 141, respectively.

Conductive layers disposed on the low-capacitance layers 111 and 112 on the back and front sides of the multilayer wiring board 40 are signal layers 131 and 132, respectively. The signal layer 132 is connected to the electronic components 61 and 62 such as the LSI chips, mounted on the front side, through bonding wires.

The signal layers 131 and 132 include ground wires, first power supply wires, second power supply wires, and signal wires, respectively. A ground via 17 is formed between the ground wires of the signal layers 131 and 132 and the ground layers 141 and 142. A first power supply via 181 is formed between the first power supply wires of the signal layers 131 and 132 and the first power supply layer 15. A second power supply via 182 is formed between the second power supply wires of the signal layers 131 and 132 and the second power supply layer 16.

It can be said that this embodiment incorporates two structures each corresponding to the structure of the third embodiment. That is, this embodiment includes a first structure in which the ground layer 142 is sandwiched between the high-capacitance layers 122 and 123 having mutually different capacitances and further sandwiched between the first and the second power supply layers 15 and 16, and a second structure in which the first power supply layer 15 is sandwiched between the high-capacitance layers 121 and 122 having mutually different capacitances and further sandwiched between the ground layers 141 and 142. These first and second structures each correspond to the structure of the third embodiment.

As described above, in this embodiment, since the capacitances of at least two of the high-capacitance layers 121, 122, and 123 differ from each other, the noise reduction effects are obtained in a plurality of frequency bands.

Also in this embodiment, instead of the high-capacitance layers 122 and 123, high-capacitance layers each having a smaller capacitance than the high-capacitance layer 121 may be formed by increasing the thickness of the insulating material having the same permittivity as that of the high-capacitance layer 121. On the other hand, instead of the high-capacitance layers 122 and 123, use may be made of high-capacitance layers obtained by reducing and increasing the thickness of the insulating material having the same permittivity as that of the high-capacitance layer 121, respectively. With this configuration, since the high-capacitance layers are made of the same insulating material, thermal expansion coefficients and so on of the respective layers are equal to each other, thus resulting in higher reliability.

In this embodiment, the ground layer 142 of a supply-ground layer pair comprised of the second power supply layer 16 and the ground layer 142 with the high-capacitance layer 123 interposed therebetween is also used in another supply-ground layer pair having the high-capacitance layer 122 interposed therebetween. Further, the first power supply layer 15 of a supply-ground layer pair comprised of the ground layer 142 and the first power supply layer 15 with the high-capacitance layer 122 interposed therebetween is also used in still another supply-ground layer pair having the high-capacitance layer 121 interposed therebetween. Accordingly, there is an effect that the total number of layers is smaller and the structure is simpler as compared with the conventional structure having a plurality of supply-ground layer pairs independent of each other.

### FIFTH TO NINTH EMBODIMENTS

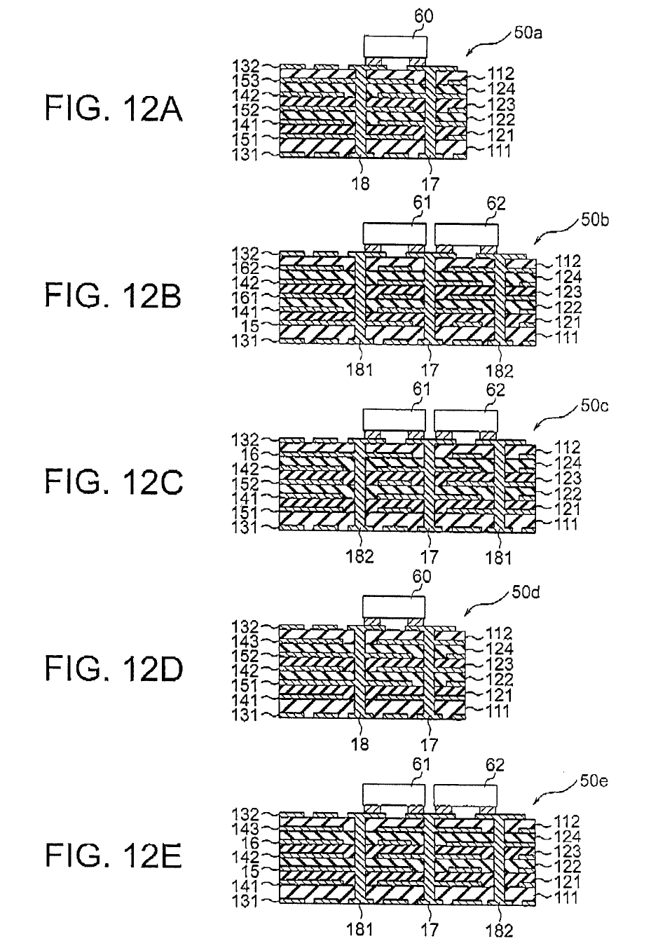

FIGS. 12A to 12E are sectional views of multilayer wiring boards according to the fifth to ninth embodiments of this invention, respectively.

In description of these embodiments, detailed explanation of portions that are the same as or equivalent to those in the first to fourth embodiments shown in FIGS. 3 to 11 will be omitted.

Referring to FIG. 12A, a multilayer wiring board 50a according to the fifth embodiment of this invention comprises low-capacitance layers 111 and 112, four high-capacitance layers 121 to 124 each having a capacitance higher than that of each of the low-capacitance layers 111 and 112, power supply layers 151 to 153, and ground layers 141 and 142. Specifically, a signal layer 131, the low-capacitance layer 111, the power supply layer 151, the high-capacitance layer 121, the ground layer 141, the high-capacitance layer 122, the power supply layer 152, the high-capacitance layer 123, the ground layer 142, the high-capacitance layer 124, the power supply layer 153, the low-capacitance layer 112, and a signal layer 132 are stacked in the order named from below.

The capacitances of at least two of the high-capacitance layers 121 to 124 differ from each other.

The signal layers 131 and 132 are disposed on the low-capacitance layers 111 and 112 on the back and front sides of the multilayer wiring board 50a, respectively. The signal layer 132 is connected to an electronic component 60 such as an LSI chip, mounted on the front side, through bonding wires.

The signal layers 131 and 132 include ground wires, power supply wires, and signal wires, respectively. A ground via 17 is formed between the ground wires and the ground layers 141 and 142. A power supply via 18 is formed between the power supply wires and the power supply layers 151 to 153.

Referring to FIG. 12B, a multilayer wiring board 50b according to the sixth embodiment of this invention comprises low-capacitance layers 111 and 112, four high-capacitance layers 121 to 124 each having a capacitance higher than that of each of the low-capacitance layers 111 and 112, a first power supply layer 15, two second power supply layers 161 and 162, and ground layers 141 and 142, Specifically, a signal layer 131, the low-capacitance layer 111, the first power supply layer 15, the high-capacitance layer 121, the ground layer 141, the high-capacitance layer 122, the second power supply layer 161, the high-capacitance layer 123, the ground layer 142, the high-capacitance layer 124, the second power supply layer 162, the low-capacitance layer 112, and a signal layer 132 are stacked in the order named from below.

The capacitances of at least two of the high-capacitance layers 121 to 124 differ from each other.

The signal layers 131 and 132 are disposed on the low-capacitance layers 111 and 112 on the back and front sides of the multilayer wiring board 50b, respectively. The signal layer 132 is connected to electronic components 61 and 62 such as LSI chips, mounted on the front side, through bonding wires.

The signal layers 131 and 132 include ground wires, first power supply wires, second power supply wires, and signal wires, respectively. A ground via 17 is formed between the ground wires and the ground layers 141 and 142. A first power supply via 181 is formed between the first power supply wires and the first power supply layer 15. A second power supply via 182 is formed between the second power supply wires and the second power supply layers 161 and 162.

Referring to FIG. 12C, a multilayer wiring board 50c according to the seventh embodiment of this invention comprises low-capacitance layers 111 and 112, four high-capacitance layers 121 to 124 each having a capacitance higher than that of each of the low-capacitance layers 111 and 112, two first power supply layers 151 and 152, a second power supply layer 16, and ground layers 141 and 142. Specifically, a signal layer 131, the low-capacitance layer 111, the first power supply layer 151, the high-capacitance layer 121, the ground layer 141, the high-capacitance layer 122, the first power supply layer 152, the high-capacitance layer 123, the ground layer 142, the high-capacitance layer 124, the second power supply layer 16, the low-capacitance layer 112, and a signal layer 132 are stacked in the order named from below.

The capacitances of at least two of the high-capacitance layers 121 to 124 differ from each other.

The signal layers 131 and 132 are disposed on the low-capacitance layers 111 and 112 on the back and front sides of the multilayer wiring board 50c, respectively. The signal layer 132 is connected to electronic components 61 and 62 such as LSI chips, mounted on the front side, through bonding wires.

The signal layers 131 and 132 include ground wires, first power supply wires, second power supply wires, and signal wires, respectively. A ground via 17 is formed between the ground wires and the ground layers 141 and 142. A first power supply via 181 is formed between the first power supply wires and the first power supply layers 151 and 152. A second power supply via 182 is formed between the second power supply wires and the second power supply layer 16.

Referring to FIG. 12D, a multilayer wiring board 50d according to the eighth embodiment of this invention comprises low-capacitance layers 111 and 112, four high-capacitance layers 121 to 124 each having a capacitance higher than that of each of the low-capacitance layers 111 and 112, power supply layers 151 and 152, and ground layers 141 to 143. Specifically, a signal layer 131, the low-capacitance layer 111, the ground layer 141, the high-capacitance layer 121, the power supply layer 151, the high-capacitance layer 122, the ground layer 142, the high-capacitance layer 123, the power supply layer 152, the high-capacitance layer 124, the ground layer 143, the low-capacitance layer 112, and a signal layer 132 are stacked in the order named from below.

The capacitances of at least two of the high-capacitance layers 121 to 124 differ from each other.

The signal layers 131 and 132 are disposed on the low-capacitance layers 111 and 112 on the back and front sides of the multilayer wiring board 50d, respectively. The signal layer 132 is connected to an electronic component 60 such as an LSI chip, mounted on the front side, through bonding wires.

The signal layers 131 and 132 include ground wires, power supply wires, and signal wires, respectively. A ground via 17 is formed between the ground wires and the ground layers 141 to 143. A power supply via 18 is formed between the power supply wires and the power supply layers 151 and 152.

Referring to FIG. 12E, a multilayer wiring board 50e according to the ninth embodiment of this invention comprises low-capacitance layers 111 and 112, four high-capacitance layers 121 to 124 each having a capacitance higher than that of each of the low-capacitance layers 111 and 112, a first power supply layer 15, a second power supply layer 16, and ground layers 141 to 143, Specifically, a signal layer 131, the low-capacitance layer 111, the ground layer 141, the high-capacitance layer 121, the first power supply layer 15, the high-capacitance layer 122, the ground layer 142, the high-capacitance layer 123, the second power supply layer 16, the high-capacitance layer 124, the ground layer 143, the low-capacitance layer 112, and a signal layer 132 are stacked in the order named from below.

The capacitances of at least two of the high-capacitance layers 121 to 124 differ from each other.

The signal layers 131 and 132 are disposed on the low-capacitance layers 111 and 112 on the back and front sides of the multilayer wiring board 50e, respectively. The signal layer 132 is connected to electronic components 61 and 62 such as LSI chips, mounted on the front side, through bonding wires.

The signal layers 131 and 132 include ground wires, first power supply wires, second power supply wires, and signal wires, respectively. A ground via 17 is formed between the ground wires and the ground layers 141 to 143. A first power supply via 181 is formed between the first power supply wires and the first power supply layer 15. A second power supply via 182 is formed between the second power supply wires and the second power supply layer 16.

In the fifth to ninth embodiments, since the capacitances of at least two of the high-capacitance layers 121 to 124 differ from each other as described above, the noise reduction effects are obtained in a plurality of frequency bands.

Also in the fifth to ninth embodiments, the required capacitances may be obtained according to the forming thicknesses of the respective capacitance layers. In this case, since the high-capacitance layers are made of the same insulating material, thermal expansion coefficients and so on of the respective layers are equal to each other, thus resulting in higher reliability.

Further, also in the fifth to ninth embodiments, since the power supply layer or the ground layer is shared between the adjacent supply-ground layer pairs, there is an effect that the total number of layers is smaller and the structure is simpler as compared with the conventional structure having a plurality of supply-ground layer pairs independent of each other.

While this invention has been described in terms of the preferred embodiments, this invention is not to be limited thereto, but can be carried out with various changes without departing from the gist of this invention.

What is claimed is:

1. A multilayer wiring board comprising first, second, and third conductive layers, a first insulating layer formed between said first and said second conductive layers, and a second insulating layer formed between said second and said third conductive layers;
said first and said second insulating layers being different in capacitance from each other.

2. The multilayer wiring board according to claim 1, wherein said first and said second insulating layers are made of insulating materials, respectively, the insulating materials being different in permittivity from each other.

3. The multilayer wiring board according to claim 1, wherein said first and said second insulating layers are different in thickness from each other.

4. A multilayer wiring board comprising first, second, third, and fourth conductive layers, a first insulating layer formed between said first and said second conductive layers, a second insulating layer formed between said second and said third conductive layers, and a third insulating layer formed between said third and said fourth conductive layers;
at least two of said first, said second, and said third insulating layers being different in capacitance from one another.

5. The multilayer wiring board according to claim 4, wherein said first, said second, and said third insulating layers are made of insulating materials, respectively, at least two of the insulating materials being different in permittivity from one another.

6. The multilayer wiring board according to claim 4, wherein at least two of said first, said second, and said third insulating layers are different in thickness from one another.

7. A multilayer wiring board comprising an inner conductive layer which is sandwiched between first and second insulating layer and which is further sandwiched between two outer conductive layers;
said inner conductive layer serving as one of a power supply layer and a ground layer;
each of said outer conductive layers serving as the other of the power supply layer and the ground layer;
said first and said second insulating layers being different in capacitance from each other.

8. The multilayer wiring board according to claim 7, wherein said first and said second insulating layers are made of insulating materials, respectively, the insulating materials being different in permittivity from each other.

9. The multilayer wiring board according to claim 7, wherein said first and said second insulating layers are different in thickness from each other.

10. A multilayer wiring board comprising:
an inner conductive layer which is sandwiched between first and second insulating layer and which is further sandwiched between two outer conductive layers; and
an additional outer conductive layer formed on one of said outer conductive layers through a third insulating layer;
said inner conductive layer serving as one of a power supply layer and a ground layer;
each of said outer conductive layers serving as the other of the power supply layer and the ground layer;
said additional outer conductive layer serving as a secondary power supply layer or a secondary ground layer;
at least two of said first, said second, and said third insulating layers being different in capacitance from one another.

11. The multilayer wiring board according to claim 10, wherein said first, said second, and said third insulating layers are made of insulating materials, respectively, at least two of the insulating materials being different in permittivity from one another.

12. The multilayer wiring board according to claim 10, wherein at least two of said first, said second, and said third insulating layers are different in thickness from one another.

13. A multilayer wiring board manufacturing method comprising the steps of:
forming conductive layers on both sides of a first capacitance layer, thereby fabricating a first member;
forming a conductive layer on one side of a second capacitance layer, thereby fabricating a second member; and
stacking together said first and said second member by pressing such that a surface, not formed with said conductive layer, of said second member is butted to one of said conductive layers of said first member;
said first and said second capacitance layers being different in capacitance from each other.

14. A multilayer wiring board manufacturing method comprising the steps of:
forming conductive layers on both sides of a first capacitance layer, thereby fabricating a first member;
forming a conductive layer on one side of a second capacitance layer, thereby fabricating a second member;
forming a conductive layer on one side of a third capacitance layer, thereby fabricating a third member; and
stacking together said first, said second, said third members by pressing such that a surface, not formed with the conductive layer, of said second member is butted to the one of said conductive layers of said first member and that a surface, not formed with the conductive layer, of said third member is butted to the other of said conductive layers of said first member;
at least two of said first, said second, and said third capacitance layers being different in capacitance from one another.
